(19) United States
(12) Patent Application Publication
(10) Pub. No.: US 2005/0001301 A1
(43) Pub. Date: Jan. 6, 2005

(54) Semiconductor device, electronic device, electronic equipment, and method of manufacturing semiconductor device

(75) Inventor: Akiyoshi Aoyagi, (US)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/833,508

(22) Filed: Apr. 28, 2004

(30) Foreign Application Priority Data
May 2, 2003 (JP) 2003-127057

(51) Int. Cl. H01L 23/02

(52) U.S. Cl. 257/686

(57) ABSTRACT

A semiconductor device includes a first semiconductor package where a first semiconductor chip is mounted, a second semiconductor package supported above the first semiconductor package so as to be disposed above the first semiconductor chip and resin disposed exposing at least a part of the first semiconductor chip, and provided between the first semiconductor chip and the second semiconductor package.

### BACKGROUND OF THE INVENTION

1. Field of the Invention

The present invention relates to a semiconductor device, an electronic device, electronic equipment, and a method of manufacturing a semiconductor device, and especially relates to devices and methods that are preferably applied to a stack structure of semiconductor packages.

2. Description of the Related Art

In a conventional semiconductor package, space-saving has been attempted by stacking semiconductor packages through solder balls. In this method, resin is filled between the stacked semiconductor packages.

In a conventional semiconductor package, however, resin is filled into the entire gap between semiconductor packages stacked through solder balls. Thus, when the resin filled between the semiconductor packages is cured, water contained in the resin is not sufficiently removed such that a part of water remains in the resin filled between the semiconductor packages. This causes a problem that, when the reflow process is implemented during a secondary mounting of the stacked semiconductor packages, water contained in the resin filled between the semiconductor packages evaporates and expands such that the separation between the semiconductor packages occurs.

In view of the above problem, the present invention is intended to provide a semiconductor device, an electronic device, electronic equipment, and a method of manufacturing a semiconductor device that can avoid the separation between semiconductor packages while preventing the displacement of stacked semiconductor packages during a secondary mounting.

### SUMMARY OF THE INVENTION

In order to solve the problem, a semiconductor device according to one aspect of the present invention includes a first semiconductor package where a first semiconductor chip is mounted, and a second semiconductor package supported above the first semiconductor package so as to be disposed above the first semiconductor chip. The semiconductor device also includes resin disposed so that at least a part of the first semiconductor chip is exposed, and provided between the first semiconductor chip and the second semiconductor package.

This enables the first and second semiconductor packages to be fixed to each other through the resin disposed on the first semiconductor chip, and enables the gap between the first and second semiconductor packages to be left even though the resin is provided between the first and second semiconductor packages. Thus, water contained in the resin between the first and second semiconductor packages can easily be removed such that the expansion of the resin between the first and second semiconductor packages can be avoided even in the case where a reflow process is implemented during a secondary mounting. As a result, the first and second semiconductor packages can be secured to each other with the resin while the separation between the first and second semiconductor packages can be avoided. This enables the displacement between the first and second semiconductor packages to be avoided.

A semiconductor device according to one aspect of the present invention includes a first semiconductor package where a first semiconductor chip is mounted, and a second semiconductor package supported above the first semiconductor package so that an end part of the second semiconductor package is disposed above the first semiconductor chip. The semiconductor device also includes resin disposed so that at least a part of the first semiconductor chip is exposed, and provided between the first semiconductor chip and the second semiconductor package.

This enables the first and second semiconductor packages to be fixed to each other through the resin disposed on the first semiconductor chip, and enables the gap between the first and second semiconductor packages to be left even though the resin is provided between the first and second semiconductor packages. In addition, the plurality of semiconductor packages can be disposed on one first semiconductor chip. Thus, the separation between the first and second semiconductor packages can be avoided while the mounting area can be further reduced, and the displacement of the first and second semiconductor packages during a secondary mounting can be prevented.

In the semiconductor device according to one aspect of the present invention, the resin is provided only on facing surfaces of the second semiconductor package and the first semiconductor chip.

This enables the first and second packages to be effectively secured to each other through the resin disposed on the first semiconductor chip without bringing the resin into contact with the first semiconductor package. Thus, the displacement of the first and second semiconductor packages, which are stacked, during a secondary mounting can be prevented while the separation between the first and second semiconductor packages can be avoided.

In the semiconductor device according to one aspect of the present invention, the resin is provided on the center part of the first semiconductor chip.

This enables the resin to be disposed on a place distant from the protruding electrodes even though the first and second semiconductor packages are electrically coupled to each other through the protruding electrodes. Thus, it can be avoided that the expansion and contraction of the resin imposes a negative effect on the protruding electrodes, enabling the endurance for temperature cycling and the like to be improved.

In the semiconductor device according to one aspect of the present invention, filler is mixed into the resin.

This enables the viscosity of the resin to be easily controlled such that dropping of the resin can be avoided, and the area where the resin is provided can be easily controlled.

In the semiconductor device according to one aspect of the present invention, the first semiconductor package includes a first carrier substrate where the first semiconductor chip is flip-chip mounted, and a resin layer provided between the first semiconductor chip and the first carrier substrate. In addition, the second semiconductor package includes a second semiconductor chip, and a second carrier substrate where the second semiconductor chip is mounted. The second semiconductor package also includes a protruding electrode bonded to the first carrier substrate and holding the second carrier substrate above the first semiconductor chip, and a sealing material sealing the second semiconductor chip.

According to this, even in the case where the types of the first and second semiconductor packages are different from each other, the separation between the first and second semiconductor packages can be avoided while the displacement of the stacked semiconductor packages during a secondary mounting is prevented such that the reliability of connection between the first and second semiconductor packages can be improved while space-saving can be achieved.

In the semiconductor device according to one aspect of the present invention, the protruding electrode is a solder ball.

This enables the first and second semiconductor packages to be electrically coupled to each other with the reflow process. The second semiconductor package therefore can effectively be mounted on the first semiconductor package.

In the semiconductor device according to one aspect of the present invention, the modulus of elasticity of the resin provided between the first semiconductor chip and the second semiconductor package is smaller than the modulus of elasticity of the resin layer provided between the first semiconductor chip and the first carrier substrate.

This enables the resin provided between the first semiconductor chip and the second semiconductor package to effectively absorb the shock imposed on the first semiconductor chip. The shock-resistance of the semiconductor chip therefore can be improved such that a plurality of semiconductor chips can be stacked while the reliability of the semiconductor chip is secured.

In the semiconductor device according to one aspect of the present invention, the first semiconductor package is a ball grid array where the first semiconductor chip is flip-chip mounted on the first carrier substrate, and the second semiconductor package is a ball grid array or chip size package where the second semiconductor chip mounted on the second carrier substrate is molded.

According to this, even in the case where general purpose packages are used, the separation between the first and second semiconductor packages can be avoided while the displacement of the stacked semiconductor packages during the secondary mounting is prevented such that the reliability of connection between packages of different types can be improved without degrading the production efficiency.

An electronic device according to one aspect of the present invention includes a first package where an electronic component is mounted, and a second package supported above the first package so as to be disposed above the electronic component. The electronic device also includes resin disposed so that at least a part of the electronic component is exposed, and provided between the electronic component and the second package.

This enables the first and second packages to be fixed to each other through the resin disposed on the electronic component, and enables the gap between the first and second packages to be left even though the resin is provided between the first and second packages. Thus, the first and second packages can be secured to each other with the resin while the separation between the first and second packages can be avoided. This enables the displacement between the first and second packages can be avoided.

Electronic equipment according to one aspect of the present invention includes a first semiconductor package where a first semiconductor chip is mounted, and a second semiconductor package supported above the first semiconductor package so as to be disposed above the first semiconductor chip. The electronic equipment also includes resin disposed so that at least a part of the first semiconductor chip is exposed, and provided between the first semiconductor chip and the second semiconductor package, a motherboard where the first semiconductor package, above which the second semiconductor package is supported, is mounted, and an electronic component coupled to the first semiconductor chip through the motherboard.

This enables the displacement of the semiconductor packages during a secondary mounting to be avoided while suppressing the degradation of the reliability of the stacked semiconductor packages. The reliability of the electronic equipment therefore can be improved while the reduction in the size and weight of the electronic equipment can be achieved.

A method of manufacturing a semiconductor device according to one aspect of the present invention includes the steps of providing resin on a first semiconductor chip mounted on a first semiconductor package, and mounting a second semiconductor package where a second semiconductor chip is mounted on the first semiconductor package so that at least a part of the first semiconductor chip is exposed from the resin.

Thus, the gap between the first and second semiconductor packages can be left even in the case where the resin is filled between the first and second semiconductor packages, enabling the separation between the first and second semiconductor packages to be avoided while preventing the displacement of the stacked semiconductor packages during a secondary mounting.

### BRIEF DESCRIPTION OF THE DRAWINGS

FIG. 1 is a sectional view schematically showing a structure of a semiconductor device according to a first embodiment of the present invention.

FIGS. 2A-2D are sectional views showing one example of a method of manufacturing the semiconductor device of FIG. 1.

FIG. 3 is a sectional view schematically showing a structure of a semiconductor device according to a second embodiment of the present invention.

FIG. 4 is a sectional view schematically showing a structure of a semiconductor device according to a third embodiment of the present invention.

FIG. 5 is a sectional view schematically showing a structure of a semiconductor device according to a fourth embodiment of the present invention.

FIG. 6 is a sectional view schematically showing a structure of a semiconductor device according to a fifth embodiment of the present invention.

### DESCRIPTION OF THE PREFERRED EMBODIMENTS

A semiconductor device and a method of manufacturing the same according to embodiments of the present invention will be described below with reference to the accompanying drawings.

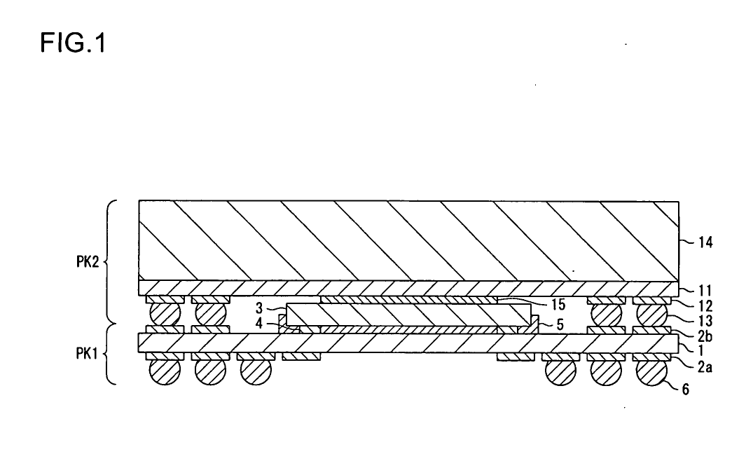

FIG. 1 is a sectional view schematically showing a structure of a semiconductor device according to a first embodiment of the present invention.

Referring to FIG.1, a semiconductor package PK1 includes a carrier substrate 1, and on both sides of the carrier substrate 1 are formed lands 2a and 2b, respectively. A semiconductor chip 3 is flip-chip mounted on the carrier substrate 1. Protruding electrodes 4 for flip-chip mounting are provided on the semiconductor chip 3. The protruding electrodes 4 provided on the semiconductor chip 3 are bonded to the lands 2b through an anisotropic conductive sheet 5 by Anisotropic Conductive Film (ACF) bonding.

Meanwhile, a semiconductor package PK2 includes a carrier substrate 11. Lands 12 are formed on a back surface of the carrier substrate 11, and protruding electrodes 13 are provided on the lands 12. A semiconductor chip is mounted on the carrier substrate 11. The carrier substrate 11, where the semiconductor chip is mounted, is sealed with a sealing resin 14. Here, the semiconductor chip may be mounted by wire bonding, or may be mounted by flip-chip mounting, on the carrier substrate 11. Otherwise, a stack structure of semiconductor chips may be mounted.

The protruding electrodes 13 are bonded to the lands 2b provided on the carrier substrate 1, and thereby the semiconductor package PK2 is mounted on the semiconductor package PK1 so that the carrier substrate 11 is disposed above the semiconductor chip 3.

Furthermore, resin 15 is provided on the semiconductor chip 3 so that at least a part of the semiconductor chip 3 is exposed. The semiconductor package PK2 is secured to the semiconductor chip 3 through the resin 15. As the resin 15, either of a resin paste or a resin sheet may be used.

This enables the semiconductor packages PK1 and PK2 to be fixed to each other through the resin 15 disposed on the semiconductor chip 3, and enables the gap between the semiconductor packages PK1 and PK2 to be left even though the resin 15 is provided between the semiconductor packages PK1 and PK2. Thus, water contained in the resin between the semiconductor packages PK1 and PK2 can easily be removed such that the expansion of the resin 15 between the semiconductor packages PK1 and PK2 can be avoided even in the case where protruding electrodes 6 are reflowed during a secondary mounting. As a result, the semiconductor packages PK1 and PK2 can be secured to each other with the resin 15 while the separation between the semiconductor packages PK1 and PK2 can be avoided. This enables the displacement between the semiconductor packages PK1 and PK2 to be avoided.

The resin 15 may be provided only on facing surfaces of the semiconductor package PK2 and the semiconductor chip 3. This enables the semiconductor packages PK1 and PK2 to be effectively secured to each other through the resin 15 provided on the semiconductor chip 3 without bringing the semiconductor package PK1 into contact with the resin 15. Thus, the displacement between the semiconductor packages PK1 and PK2, which are stacked, during the secondary mounting can be avoided while the separation between the semiconductor packages PK1 and PK2 can be avoided.

The resin 15 may be provided on the center part of the semiconductor chip 3. This enables the resin 15 to be disposed on a place distant from the protruding electrodes 13 even though the semiconductor packages PK1 and PK2 are electrically coupled to each other through the protruding electrodes 13. Thus, the expansion and contraction of the resin 15 can be prevented from imposing a negative effect on the protruding electrodes 13, enabling the endurance for temperature cycling and the like to be improved.

The modulus of elasticity of the resin 15 provided between the semiconductor chip 3 and the semiconductor package PK2 is preferably smaller than that of the anisotropic conductive sheet 5 provided between the semiconductor chip 3 and the carrier substrate 1. This enables the resin 15 to effectively absorb the shock imposed on the semiconductor chip 3. The shock-resistance of the semiconductor chip 3 therefore can be improved such that the semiconductor packages PK1 and PK2 can be stacked while the reliability of the semiconductor chip 3 is secured.

Fillers such as silica and alumina may be mixed into the resin 15. This enables the viscosity of the resin 15 to be easily controlled such that dropping of the resin 15 can be avoided, and the area where the resin 15 is provided can easily be controlled.

The resin 15 on the semiconductor chip 3 may be disposed on only one place. Otherwise, the resin 15 may be disposed on the semiconductor chip 3 in a dispersed manner. By disposing the resin 15 on the semiconductor chip 3 in a dispersed manner, channels for letting out water contained in the resin 15 can be ensured on the semiconductor chip 3. Water contained in the resin 15 therefore can be reduced even in the case where the gap between the semiconductor chip 3 and the semiconductor package PK2 is narrow.

As the carrier substrates 1 and 11, for example, a double-sided substrate, a multi-layered wiring substrate, a build-up substrate, a tape substrate, or a film substrate can be used. As the material of the carrier substrates 1 and 11, for example, polyimide resin, glass epoxy resin, BT resin, a composite of aramid and epoxy, or ceramic can be used. Meanwhile, as the protruding electrodes 4, 6, and 13, for example, a Au bump, a Cu bump or Ni bump covered by a solder material and the like, or a solder ball can be used.

In the case where the semiconductor packages PK1 and PK2 are coupled to each other through the protruding electrodes 13, metal bonding such as solder bonding and alloy bonding may be used. Otherwise, pressure bonding such as ACF bonding, Nonconductive Film (NCF) bonding, Anisotropic Conductive Paste (ACP) bonding, and Nonconductive Paste (NCP) bonding may be used. Although described was a method where ACF bonding is used when the semiconductor chip 3 is flip-chip mounted on the carrier substrate 1 through the protruding electrodes 4, in the above-described embodiment, pressure bonding such as NCF bonding, ACP bonding, and NCP bonding may be used, otherwise metal bonding such as solder bonding and alloy bonding may be used.

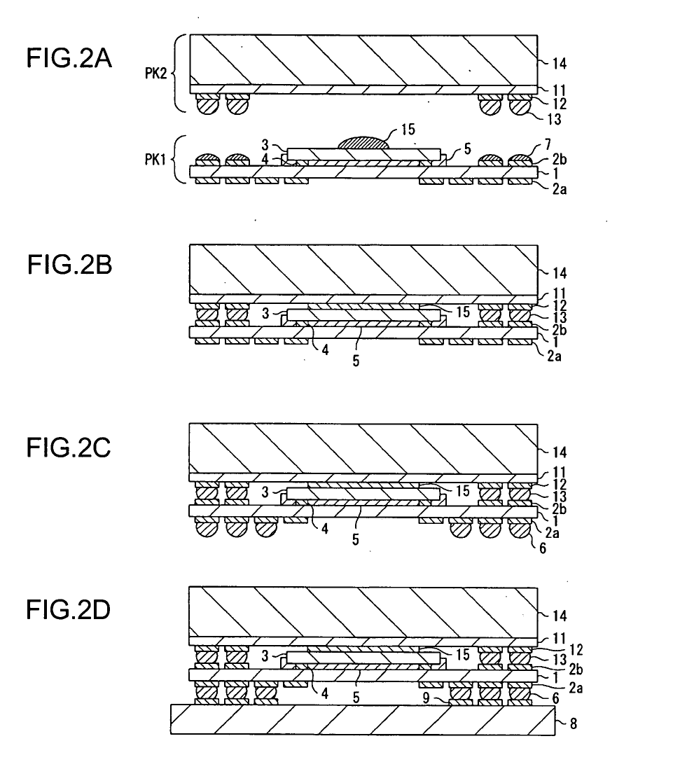

FIGS. 2A-2D are sectional views showing one example of a method of manufacturing the semiconductor device of FIG. 1.

Referring to FIG. 2A, in the case where the semiconductor package PK2 is to be stacked on the semiconductor package PK1, solder balls are formed on the lands 12 of the semiconductor package PK2 as the protruding electrodes 13, and flux 7 is provided on the lands 2b of the carrier substrate 1. The resin 15 is provided on the semiconductor chip 3 by using a dispenser and the like.

Next, the semiconductor package PK2 is mounted on the semiconductor package PK1 as shown in FIG. 2B. Then, the protruding electrodes 13 are melted by implementing a reflow process for the protruding electrodes 13, so as to bond the protruding electrodes 13 onto the lands 2b.

Here, when the protruding electrodes 13 are bonded onto the lands 2b, the resin 15 is preferably maintained at an A-stage state (a state where the resin is softened due to temperature rising), or a B-stage state (a state where the viscosity of the resin increases due to temperature rising). This enables the protruding electrodes 13 to be disposed on the lands 2b in a self-aligned manner by the surface tension of the protruding electrodes 13 when melted such that the semiconductor package PK2 can precisely be disposed on the semiconductor package PK1. Then, after the protruding electrodes 13 are bonded onto the lands 2b, the resin 15 is cured at a temperature lower than that during the reflow of the protruding electrodes 13, so as to transform the resin 15 into a C-stage state (a cured state).

By disposing the resin 15 on the semiconductor chip 3 so that at least a part of the semiconductor chip 3 is exposed, the semiconductor packages PK1 and PK2 are secured to each other through the semiconductor chip 3 while channels for letting out water contained in the resin 15 are ensured such that the residual volume of water contained in the resin 15 can be reduced.

Next, the protruding electrodes 6 for mounting the carrier substrate 1 on a motherboard 8 are formed on the lands 2a, which are provided on a back surface of the carrier substrate 1, as shown in FIG. 2C.

Then, the carrier substrate 1 where the protruding electrodes 6 are formed is mounted on the motherboard 8 as shown in FIG. 2D. Then, the protruding electrodes 6 are bonded onto the lands 9 of the motherboard 8 by implementing a reflow process for the protruding electrodes 6.

The reflow process for the protruding electrodes 6 can be implemented after water contained in the resin 15 between the semiconductor packages PK1 and PK2 has been almost completely removed, since the resin 15 is provided on the semiconductor chip 3 so that at least a part of the semiconductor 13 is exposed. The resin 15 therefore can be prevented from expanding during the reflow of the protruding electrodes 6, enabling the separation between the semiconductor packages PK1 and PK2 to be avoided. Even in the case where the protruding electrodes 13 are reflowed again during the reflow of the protruding electrodes 6, the semiconductor packages PK1 and PK2 can be still fixed to each other with the resin 15, enabling the displacement between the semiconductor packages PK1 and PK2 to be avoided.

In the above-described embodiment, described was a method where the flux 7 is provided on the lands 2b of the carrier substrate 1, and the protruding electrodes 13 are provided on the lands 12 of the carrier substrate 11 in order to mount the semiconductor package PK2 on the semiconductor package PK1. Instead of this, the protruding electrodes 13 may be provided on the lands 2b of the carrier substrate 1 while the flux 7 may be provided on the lands 12 of the carrier substrate 11. A solder paste may be used instead of the flux 7. In addition, although described was a method where the resin 15 of a paste state is provided on the semiconductor chip 3 by using a dispenser and the like in the embodiment, the resin 15 of a sheet state may be provided on the semiconductor chip 3.

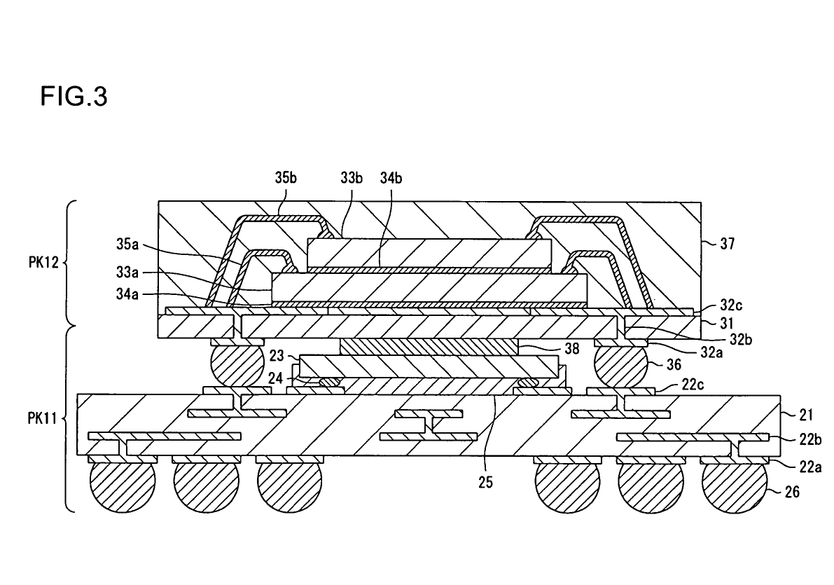

FIG. 3 is a sectional view schematically showing a structure of a semiconductor device according to a second embodiment of the present invention.

Referring to FIG.3, a semiconductor package PK11 includes a carrier substrate 21. Lands 22a and 22c are formed on both sides of the carrier substrate 21, respectively, and an internal wiring 22b is formed inside the carrier substrate 21. A semiconductor chip 23 is flip-chip mounted on the carrier substrate 21. Protruding electrodes 24 for flip-chip mounting are provided on the semiconductor chip 23. The protruding electrodes 24 provided on the semiconductor chip 23 are bonded to the lands 22c through an anisotropic conductive sheet 25 by ACF bonding. On the lands 22a provided on a back surface of the carrier substrate 21, provided are protruding electrodes 26 for mounting the carrier substrate 21 on a motherboard.

Meanwhile, a semiconductor package PK12 includes a carrier substrate 31. Lands 32a and 32c are formed on both sides of the carrier substrate 31, respectively, and an internal wiring 32b is formed inside the carrier substrate 31. A semiconductor chip 33a is face-up mounted on the carrier substrate 31 through an adhesive layer 34a. The semiconductor chip 33a is wire-bonded to the lands 32c through conductive wires 35a. Furthermore, a semiconductor chip 33b is face-up mounted on the semiconductor chip 33a, avoiding the conductive wires 35a. The semiconductor chip 33b is fixed on the semiconductor chip 33a through an adhesive layer 34b and is wire-bonded to the lands 32c through conductive wires 35b.

On the lands 32a provided on a back surface of the carrier substrate 31, provided are protruding electrodes 36 for mounting the carrier substrate 31 on the carrier substrate 21 so that the carrier substrate 31 is held above the semiconductor chip 23. The protruding electrodes 36 are disposed avoiding the area where the semiconductor chip 23 is mounted. For example, the protruding electrodes 36 may be disposed on the periphery of the back surface of the carrier substrate 31. The carrier substrate 31 is mounted on the carrier substrate 21 by bonding the protruding electrodes 36 to the lands 22c provided on the carrier substrate 21.

Sealing resin 37 is provided on the surface of the carrier substrate 31 where the semiconductor chips 33a and 33b are mounted. The semiconductor chips 33a and 33b are sealed by the sealing resin 37. Here, when the semiconductor chips 33a and 33b are sealed by the sealing resin 37, for example, mold forming using thermosetting resin such as epoxy resin is available.

Resin 38 is provided on the semiconductor chip 23 so that at least a part of the semiconductor chip 23 is exposed. The semiconductor package PK12 is secured to the semiconductor chip 23 through the resin 38.

According to this, even in the case where packages of different types are stacked, the resin 38 can be provided between the carrier substrates 21 and 31 while a gap is left between the carrier substrates 21 and 31, which are coupled to each other through the protruding electrodes 36. Thus, space-saving when the semiconductor chips 23, 33a, and 33b, whose sizes or types are different from each other, are mounted can be achieved, while the separation between the semiconductor packages PK11 and PK12 can be avoided with preventing the displacement of the semiconductor packages PK11 and PK12, which are stacked, during a secondary mounting.

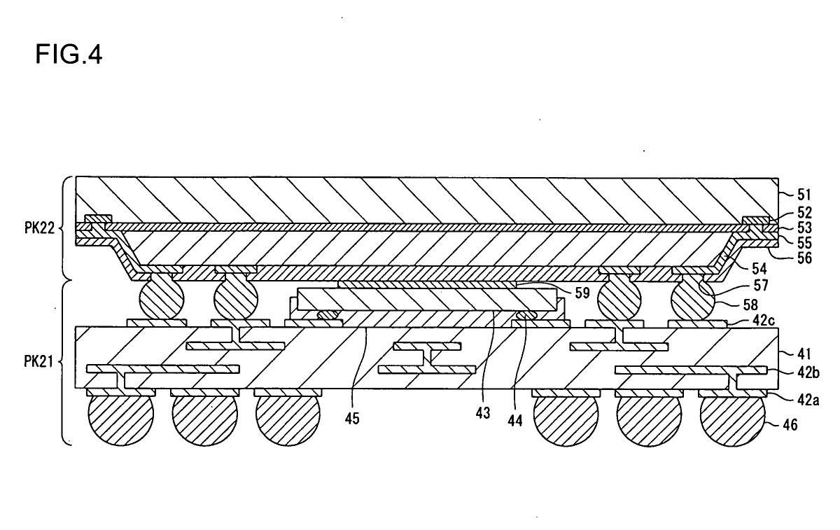

FIG. 4 is a sectional view schematically showing a structure of a semiconductor device according to a third embodiment of the present invention.

Referring to FIG. 4, a semiconductor package PK21 includes a carrier substrate 41. Lands 42a and 42c are formed on both sides of the carrier substrate 41, respectively, and an internal wiring 42b is formed inside the carrier substrate 41. A semiconductor chip 43 is flip-chip mounted on the carrier substrate 41. Protruding electrodes 44 for flip-chip mounting are provided on the semiconductor chip 43. The protruding electrodes 44 provided on the semiconductor chip 43 are bonded to the lands 42c through an anisotropic conductive sheet 45 by ACF bonding. On the lands 42a provided on a back surface of the carrier substrate 41, provided are protruding electrodes 46 for mounting the carrier substrate 41 on a motherboard.

Meanwhile, a semiconductor package PK22 includes a carrier substrate 51. To the semiconductor chip 51, provided are electrode pads 52, and provided is an insulating film 53 so that the electrode pads 52 are exposed. A stress relieving layer 54 is formed on the semiconductor chip 51 so that the electrode pads 52 are exposed. A rewiring 55 extended on the stress relieving layer 54 is formed on the electrode pads 52. A solder resist film 56 is formed on the rewiring 55, and openings 57 for exposing the rewiring 55 on the stress relieving layer 54 are formed in the solder resist film 56. Protruding electrodes 58 for face-down mounting the semiconductor chip 51 on the carrier substrate 41 are provided on the rewiring 55 exposed through the openings 57 so that the semiconductor package PK22 is held above the semiconductor chip 43.

The protruding electrodes 58 are disposed avoiding the area where the semiconductor chip 43 is mounted. For example, the protruding electrodes 58 may be disposed on the periphery of the semiconductor chip 51. The protruding electrodes 58 are-bonded onto the lands 42c provided on the carrier substrate 41 so as to mount the semiconductor package PK22 on the carrier substrate 41.

Resin 59 is provided on the semiconductor chip 43 so that at least a part of the semiconductor chip 43 is exposed. The semiconductor package PK22 is secured to the semiconductor chip 43 through the resin 59.

According to this, even in the case where a Wafer level-Chip Size Package (W-CSP) is stacked on the semiconductor package PK21, the resin 59 can be provided between the carrier substrate 41 and the semiconductor chip 51 while a gap is left between the carrier substrate 41 and the semiconductor chip 51, which are coupled to each other through the protruding electrodes 58. Thus, even in the case where the types or sizes of the semiconductor chips 43 and 51 are different from each other, the semiconductor chip 51 can be three-dimensionally mounted on the semiconductor chip 43 without interposing a carrier substrate between the semiconductor chips 43 and 51, while the separation between the semiconductor packages PK21 and PK22 can be avoided with preventing the displacement of the semiconductor packages PK21 and PK22, which are stacked, during a secondary mounting. As a result, the increase in the total height when the semiconductor chips 43 and 51 are stacked can be suppressed while the degradation of the reliability of the semiconductor chips 43 and 51 three-dimensionally mounted is suppressed, enabling space-saving when the semiconductor chips 43 and 51 are mounted.

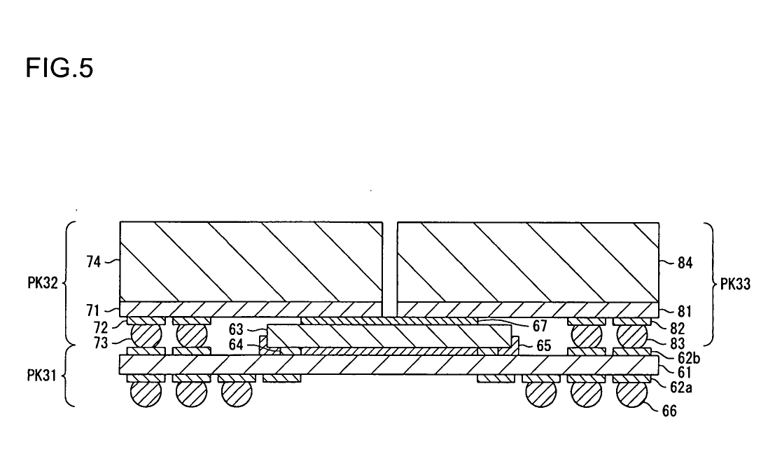

FIG. 5 is a sectional view schematically showing a structure of a semiconductor device according to a fourth embodiment of the present invention.

Referring to FIG. 5, a semiconductor package PK31 includes a carrier substrate 61, and on both sides of the carrier substrate 61 formed are lands 62a and 62b, respectively. A semiconductor chip 63 is flip-chip mounted on the carrier substrate 61. Protruding electrodes 64 for flip-chip mounting are provided on the semiconductor chip 63. The protruding electrodes 64 provided on the semiconductor chip 63 are bonded to the lands 62b through an anisotropic conductive sheet 65 by ACF bonding.

Meanwhile, semiconductor packages PK32 and PK33 include carrier substrates 71 and 81, respectively. Lands 72 and 82 are formed on back surfaces of the carrier substrates 71 and 81, and protruding electrodes 73 and 83 such as solder balls are provided on the lands 72 and 82, respectively. A semiconductor chip is mounted on each of the carrier substrates 71 and 81. The carrier substrates 71 and 81, where the semiconductor chip is mounted, are sealed with sealing resin 74 and 84, respectively.

Then, the protruding electrodes 73 and 83 each are bonded to the lands 62b provided on the carrier substrate 61, and thereby the plurality of semiconductor packages (the semiconductor packages PK32 and PK33) is mounted on the semiconductor package PK31 so that each of the end parts of the carrier substrates 71 and 81 is disposed above the semiconductor chip 63.

Resin 67 is provided on the semiconductor chip 63 so that at least a part of the semiconductor chip 63 is exposed. The end parts of the semiconductor packages PK32 and PK33 are secured to the semiconductor chip 63 through the resin 67.

This enables the plurality of semiconductor packages (the semiconductor packages PK32 and PK33) to be fixed on the semiconductor package PK31 at the same time through the resin 67 disposed on the semiconductor chip 63. Even in the case where the resin 67 is provided between the semiconductor packages PK32 and PK33, and the semiconductor package PK31, therefore, a gap can be left between the semiconductor packages PK32 and PK33, and the semiconductor package PK31 while the complication of the manufacturing processes are suppressed. Thus, the separation between the semiconductor packages PK32 and PK33, and the semiconductor package PK31 can be avoided while the mounting area can be further reduced, and the displacement of the semiconductor packages PK31, PK32, and PK33 during a secondary mounting can be prevented.

Here, in the case where the resin 67 is provided between the semiconductor chip 63 and each of the semiconductor packages PK32 and PK33, each of the semiconductor packages PK32 and PK33 may be disposed on the semiconductor chip 63 after the resin 67 is provided on the semiconductor chip 63. Otherwise, the resin 67 may be provided on the semiconductor chip 63 through the gap between the semiconductor packages PK32 and PK33 after each of the semiconductor packages PK32 and PK33 is disposed on the semiconductor chip 63.

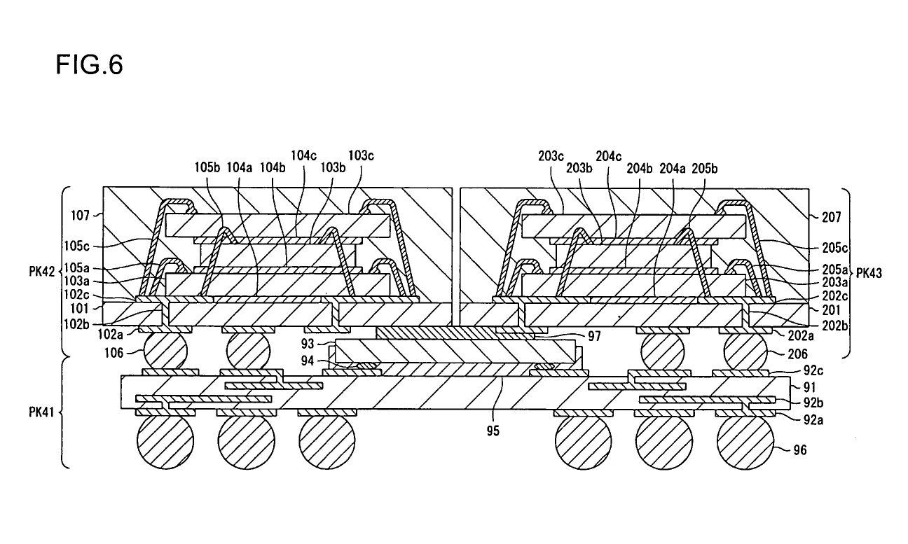

FIG. 6 is a sectional view schematically showing a structure of a semiconductor device according to a fifth embodiment of the present invention.

Referring to FIG. 6, a semiconductor package PK41 includes a carrier substrate 91. Lands 92a and 92c are formed on both sides of the carrier substrate 91, respectively, and an internal wiring 92b is formed inside the carrier substrate 91. A semiconductor chip 93 is flip-chip mounted on the carrier substrate 91. Protruding electrodes 94 for flip-chip mounting are provided on the semiconductor chip 93. The protruding electrodes 94 provided on the semiconductor chip 93 are bonded to the lands 92c through an anisotropic conductive sheet 95 by ACF bonding. On the lands 92a provided on a back surface of the carrier substrate 91, provided are protruding electrodes 96 for mounting the carrier substrate 91 on a motherboard.

Meanwhile, semiconductor packages PK42 and PK43 include carrier substrates 101 and 201, respectively. Lands 102a and 202a are formed on back surfaces of the carrier substrates 101 and 201, respectively. Lands 102c and 202c are formed on front surfaces of the carrier substrates 101 and 201, respectively. Internal wirings 102b and 202b are formed inside the carrier substrates 101 and 201, respectively.

Semiconductor chips 103a and 203a are face-up mounted on the carrier substrates 101 and 201 through adhesive layers 104a and 204a, respectively. The semiconductor chips 103a and 203a are wire-bonded to the lands 102c and 202c through conductive wires 105a and 205a, respectively. Furthermore, semiconductor chips 103b and 203b are face-up mounted on the semiconductor chips 103a and 203a, avoiding the conductive wires 105a and 205a, respectively. The semiconductor chips 103b and 203b are fixed on the semiconductor chips 103a and 203a through adhesive layers 104b and 204b and are wire-bonded to the lands 102c and 202c through conductive wires 105b and 205b. In addition, semiconductor chips 103c and 203c are face-up mounted on the semiconductor chips 103b and 203b, avoiding the conductive wires 105b and 205b, respectively. The semiconductor chips 103c and 203c are fixed on the semiconductor chips 103b and 203b through adhesive layers 104c and 204c and are wire-bonded to the lands 102c and 202c through conductive wires 105c and 205c.

On the lands 102a and 202a provided on back surfaces of the carrier substrates 101 and 201, provided are protruding electrodes 106 and 206 for mounting the carrier substrates 101 and 201 on the carrier substrate 91 so that each of the carrier substrates 101 and 201 is held above the semiconductor chip 93. The protruding electrodes 106 and 206 are preferably disposed on at least four corners of the carrier substrates 101 and 201, respectively. For example, the protruding electrodes 106 and 206 may be disposed in a U-shape.

Then, the protruding electrodes 106 and 206 each are bonded to the lands 92c provided on the carrier substrate 91, and thereby each of the carrier substrates 101 and 201 can be mounted on the carrier substrate 91 so that each of the end parts of the carrier substrates 101 and 201 is disposed above the semiconductor chip 93.

Sealing resin 107 and 207 is provided on the surfaces of the carrier substrates 101 and 201 where the semiconductor chips 103a through 103c, and 203a through 203c are mounted, respectively. The semiconductor chips 103a through 103c, and 203a through 203c are sealed by the sealing resin 107 and 207.

Resin 97 is provided on the semiconductor chip 93 so that at least a part of the semiconductor chip 93 is exposed. End parts of the semiconductor packages PK42 and PK43 are secured to the semiconductor chip 93 through the resin 97.

Thus, the plurality of semiconductor packages (the semiconductor packages PK42 and PK43) can be disposed above one semiconductor chip (the semiconductor chip 93) such that the semiconductor chips 93, 103a through 103c, and 203a through 203c of different types can be three-dimensionally mounted while the mounting area can be reduced. In addition, the displacement of the semiconductor packages PK41, PK42, and PK43 during a secondary mounting can be avoided while the separation between the semiconductor packages PK42 and PK43, and the semiconductor package PK41 can be prevented.

The above-described semiconductor device can be applied to, for example, electronic equipment such as a liquid crystal-display, a cellular phone, a portable information terminal, a video camera, a digital camera, a Mini Disc (MD) player so as to improve the reliability of the electronic equipment with reducing the size and weight of the electronic equipment.

Although a method of stacking semiconductor packages was described by way of example in the above-described embodiments, the present invention is not necessarily limited to a method of stacking semiconductor packages but may be applied to a method of stacking, for example, ceramic elements such as surface acoustic wave (SAW) elements, optical elements such as optical modulators and optical switches, and sensors of various types such as magnetic sensors and bio sensors.

1. A semiconductor device, comprising:
a first semiconductor package where a first semiconductor chip is mounted;
a second semiconductor package supported above the first semiconductor package so as to be disposed above the first semiconductor chip; and
resin disposed exposing at least a part of the first semiconductor chip, and provided between the first semiconductor chip and the second semiconductor package.

2. A semiconductor device, comprising:
a first semiconductor package where a first semiconductor chip is mounted;
a second semiconductor package supported above the first semiconductor package so that an end part of the second semiconductor package is disposed above the first semiconductor chip; and
resin disposed exposing at least a part of the first semiconductor chip, and provided between the first semiconductor chip and the second semiconductor package.

3. The semiconductor device according to claim 1, wherein the resin is provided only on facing surfaces of the second semiconductor package and the first semiconductor chip.

4. The semiconductor device according to claim 1, wherein the resin is provided on a center part of the first semiconductor chip.

5. The semiconductor device according to claim 1, wherein filler is mixed into the resin.

6. The semiconductor device according to claim 1, wherein:
the first semiconductor package comprises:
a first carrier substrate where the first semiconductor chip is flip-chip mounted; and
a resin layer provided between the first semiconductor chip and the first carrier substrate; and
the second semiconductor package comprises:
a second semiconductor chip;
a second carrier substrate where the second semiconductor chip is mounted;
a protruding electrode bonded to the first carrier substrate and holding the second carrier substrate above the first semiconductor chip; and
a sealing member sealing the second semiconductor chip.

7. The semiconductor device according to claim 6, wherein the protruding electrode is a solder ball.

8. The semiconductor device according to claim 6, wherein a modulus of elasticity of the resin provided between the first semiconductor chip and the second semiconductor package is smaller than a modulus of elasticity of the resin layer provided between the first semiconductor chip and the first carrier substrate.

9. The semiconductor device according to claim 6, wherein the first semiconductor package is a ball grid array where the first semiconductor chip is flip-chip mounted on the first carrier substrate, and the second semiconductor package is a ball grid array or chip size package where the second semiconductor chip mounted on the second carrier substrate is molded.

10. An electronic device, comprising:
a first package where an electronic component is mounted;
a second package supported above the first package so as to be disposed above the electronic component; and
resin disposed exposing at least a part of the electronic component, and provided between the electronic component and the second package.

11. Electronic equipment, comprising:
a first semiconductor package where a first semiconductor chip is mounted;
a second semiconductor package supported above the first semiconductor package so as to be disposed above the first semiconductor chip;
resin disposed exposing at least a part of the first semiconductor chip, and provided between the first semiconductor chip and the second semiconductor package;
a motherboard where the first semiconductor package, above which the second semiconductor package is supported, is mounted; and
an electronic component coupled to the first semiconductor chip through the motherboard.

12. A method of manufacturing a semiconductor device, comprising:
providing resin on a first semiconductor chip mounted on a first semiconductor package; and
mounting a second semiconductor package where a second semiconductor chip is mounted on the first semiconductor package so that at least a part of the first semiconductor chip is exposed from the resin.

13. The semiconductor device according to claim 2, wherein the resin is provided only on facing surfaces of the second semiconductor package and the first semiconductor chip.

14. The semiconductor device according to claim 2, wherein the resin is provided on a center part of the first semiconductor chip.

15. The semiconductor device according to claim 3, wherein the resin is provided on a center part of the first semiconductor chip.

16. The semiconductor device according to claim 2, wherein filler is mixed into the resin.

17. The semiconductor device according to claim 3, wherein filler is mixed into the resin.

18. The semiconductor device according to claim 4, wherein filler is mixed into the resin.

19. The semiconductor device according to claim 2, wherein:
the first semiconductor package comprises:
a first carrier substrate where the first semiconductor chip is flip-chip mounted; and
a resin layer provided between the first semiconductor chip and the first carrier substrate; and
the second semiconductor package comprises:
a second semiconductor chip;
a second carrier substrate where the second semiconductor chip is mounted;
a protruding electrode bonded to the first carrier substrate and holding the second carrier substrate above the first semiconductor chip; and
a sealing member sealing the second semiconductor chip.

20. The semiconductor device according to claim 3, wherein:
the first semiconductor package comprises:
a first carrier substrate where the first semiconductor chip is flip-chip mounted; and
a resin layer provided between the first semiconductor chip and the first carrier substrate; and
the second semiconductor package comprises:
a second semiconductor chip;
a second carrier substrate where the second semiconductor chip is mounted;
a protruding electrode bonded to the first carrier substrate and holding the second carrier substrate above the first semiconductor chip; and
a sealing member sealing the second semiconductor chip.
